(19) United States
(12) Patent Application Publication
(10) Pub. No.: US 2022/0396065 A1
(43) Pub. Date: Dec. 15, 2022

(54) HEAT DISSIPATION SHEET AND METHOD FOR PRODUCING SAME

(71) Applicant: TEIJIN LIMITED, Osaka-shi, Osaka (JP)

(72) Inventors: Masanori MAEDA, Osaka-shi, Osaka (JP); Yoshinori IKEDA, Osaka-shi, Osaka (JP); Masayuki CHOKAI, Osaka-shi, Osaka (JP); Takuya MURAKAMI, Osaka-shi, Osaka (JP)

(73) Assignee: TEIJIN LIMITED, Osaka-shi, Osaka (JP)

(21) Appl. No.: 17/774,718

(22) PCT Filed: Nov. 6, 2020
(86) PCT No.: PCT/JP2020/041595

§ 371 Date: May 5, 2022

(30) Foreign Application Priority Data
Nov. 7, 2019 (JP) 2019-202456

(51) Int. Cl. B32B 38/00; B32B 5/16; B32B 5/30; B32B 7/12; B32B 18/00

(52) U.S. Cl. CPC B32B 38/0004; B32B 5/16; B32B 5/30; B32B 7/12; B32B 18/00; B32B 2250/02; B32B 2250/44; B32B 2260/025; B32B 2260/046; B32B 2264/107; B32B 2264/201; B32B 2307/308; B32B 2307/732; B32B 2307/204; B32B 2307/302; B32B 2307/304; B32B 2457/00

(57) ABSTRACT

An object of the present invention is to provide a heat dissipation sheet having high thermal conductivity in the thickness direction. The present invention provides a heat dissipation sheet having a structure in which at least two thermally conductive insulation layers are laminated, wherein the lamination direction of the thermally conductive insulation layers is substantially perpendicular to the thickness direction of the heat dissipation sheet, and wherein for the entire cross-section perpendicular to the in-plane direction of the heat dissipation sheet, the thermally conductive insulation layer contains 75 to 97% by area of insulating particles, 3 to 25% by area of a binder resin, and 10% by area or less of voids.

### FIELD

The present disclosure relates to a heat dissipation sheet and a method of manufacturing the same, and more particularly, to a heat dissipation sheet having electrical insulation properties and capable of effectively dissipating heat generated from components such as a semiconductor element, a power source, and a light source used in electrical products. The present disclosure also relates to a method of manufacturing such a heat dissipation sheet.

### BACKGROUND

The heat dissipation sheet is a thermally conductive member that is sandwiched between a heat source and a coolant and is used to dissipate heat from the heat source to the coolant. The heat dissipation sheet is required to have high thermal conductivity in the thickness direction of the sheet. In the previous studies, in order to obtain a heat dissipation sheet having high thermal conductivity in the thickness direction, a laminate obtained by laminating primary sheet materials having high thermal conductivity in the in-plane direction was sliced along the direction of the lamination to form a sheet.

For example, there is a case in which primary sheet materials having high thermal conductivity in the in-plane direction are laminated and cut. In this example, tapes made of ultra-high-molecular-weight polyethylene and adhesive layers are alternately laminated and cut perpendicularly to the plane direction of the tape, in order to obtain a sheet having a thermal conductivity of 38 W/(m·K) in the thickness direction (Patent Document 1).

In another example, a sheet having a thermal conductivity of 27 W/(m·K) in the thickness direction was obtained by laminating and pressure-bonding primary sheet materials, in which 70% by volume of plate-shaped boron nitride powder was filled in a mixture of an acrylic acid ester copolymer resin and a phosphate ester flame retardant, and then by cutting the resultant laminate (Patent Document 2). In Patent Document 2, it is disclosed that plate-shaped boron nitride particles are oriented along their long axis direction with respect to the thickness direction of the sheet.

In still another example, a sheet having a thermal resistivity 0.25 K/W in the thickness direction was obtained by laminating primary sheet materials in which 65% by weight of plate-shaped boron nitride powder and 1.7% by weight of agglomerated powder of plate-shaped boron nitride are filled in a thermoplastic fluororesin, then by subjecting the laminate to the thermal compression bonding and then by vertically cutting the laminate (Patent Document 3). From the thermal resistivity and the measured sheet geometry (1 cm×1 cm×0.30 mm), the thermal conductivity is estimated to be 12 W/(m·K).

### RELATED ART

### Patent Literature

[Patent Document 1] JP-A-2019-131705
[Patent Document 2] JP-A-2016-222925
[Patent Document 3] JP-A-2019-108496

### SUMMARY

### Technical Problem

In a heat dissipation sheet of prior art obtained by slicing the laminate along the lamination direction, the filling rate of the boron nitride particles in primary sheet materials used for the production of the laminate was low, and therefore the thermal conductivity in the thickness direction of the resulting heat dissipation sheet was in some cases insufficient.

The present invention has been made against the background of such problems of the prior art. An object of the present invention is to provide a heat dissipation sheet having excellent thermal conductivity in the thickness direction.

### Solution to Problem

The inventors have found that the above problem is solved by the following embodiments:

### Embodiment 1

A heat dissipation sheet having a structure in which at least two thermally conductive insulation layers are laminated,

wherein the lamination direction of the thermally conductive insulation layers is substantially perpendicular to the thickness direction of the heat dissipation sheet, and

wherein for the entire cross-section perpendicular to the in-plane direction of the heat dissipation sheet, the thermally conductive insulation layer contains 75 to 97% by area of insulating particles, 3 to 25% by area of a binder resin, and 10% by area or less of voids.

### Embodiment 2

The heat dissipation sheet according to Embodiment 1, further comprising an adhesive insulation layer arranged between the at least two thermally conductive insulation layers.

### Embodiment 3

The heat dissipation sheet according to Embodiment 1 or 2, wherein the thermally conductive insulation layers represent at least 50% by volume of the heat dissipation sheet.

### Embodiment 4

The heat dissipation sheet according to Embodiment 2 or 3, wherein the thickness of the thermally conductive insulation layer in the lamination direction is at least twice the thickness of the adhesive insulation layer in the lamination direction.

### Embodiment 5

The heat dissipation sheet according to one of Embodiments 1 to 4, wherein the insulating particles comprise flat-shaped particles that are deformed.

### Embodiment 6

The heat dissipation sheet according to one of Embodiments 1 to 5, wherein the insulating particles include 50% by volume or more of boron nitride particles.

### Embodiment 7

The heat dissipation sheet according to one of Embodiments 1 to 6, wherein a melting point or a thermal decomposition temperature of the binder resin is 150° C. or higher.

### Embodiment 8

The heat dissipation sheet according to one of Embodiments 1 to 7, wherein the binder resin is an aramid resin.

### Embodiment 9

The heat dissipation sheet according to one of Embodiments 1 to 8, having the thermal conductivity in the thickness direction of 20 W/(m·K) or more, and the dielectric breakdown voltage of 5 kV/mm or more.

### Embodiment 10

The heat dissipation sheet according to one of Embodiments 1 to 9, having 6 or less of relative permittivity at 1 GHz.

### Embodiment 11

A method for manufacturing the heat dissipation sheet according to one of Embodiments 1 to 10, comprising:

providing thermally conductive insulation sheets,

laminating the at least two thermally conductive insulation sheets to obtain a laminate, and

slicing the laminate substantially along the lamination direction of the thermally conductive insulation sheets to obtain a heat dissipation sheet,

wherein for the entire cross-section of the thermally conductive insulation sheet perpendicular to the in-plane direction, the thermally conductive insulation sheet contains 75 to 97% by area of insulating particles, 3 to 25% by area of a binder resin, and 10% by area or less of voids.

### Embodiment 12

The method according to Embodiment 11, in which, when laminating the at least two thermally conductive insulation sheets, an adhesive insulation material is further arranged between the thermally conductive insulation sheets.

### Embodiment 13

The method according to Embodiment 11 or 12, in which the thermally conductive insulation sheet has the thermal conductivity of 30 W/(m·K) or more in the in-plane direction.

### Embodiment 14

The method according to one of Embodiments 11 to 13, wherein the insulating particles comprise flat-shaped particles.

### Embodiment 15

The method according to one of Embodiments 11 to 14, wherein the insulating particles include 50% by volume or more of boron nitride particles.

### Advantageous Effects of Invention

According to the present invention, it is possible to provide a heat dissipation sheet having excellent thermal conductivity in the thickness direction.

### BRIEF DESCRIPTION OF DRAWINGS

FIG. 1 shows a schematic cross-sectional view of the heat dissipation sheet according to an embodiment of the present disclosure.

FIG. 2 shows a schematic cross-sectional view of the thermally conductive insulation layer composing the heat dissipation sheet according to one embodiment of the present disclosure.

FIG. 3 shows a schematic cross-sectional view of the thermally conductive insulation layer composing the heat dissipation sheet according to another embodiment of the present disclosure.

FIG. 4 shows a schematic cross-sectional view of a thermally conductive insulation layer composing a heat dissipation sheet according to prior art.

FIG. 5 shows a SEM photograph of a cross-section perpendicular to the in-plane direction of the thermally conductive insulation sheet according to Reference Example 1.

FIG. 6 shows a SEM photograph of a cross-section perpendicular to the in-plane direction of the thermally conductive insulation sheet according to Reference Example 2.

FIG. 7 shows a SEM photograph of a cross-section perpendicular to the in-plane direction of the thermally conductive insulation sheet according to Reference Example 3.

FIG. 8 shows a SEM photograph of a cross-section perpendicular to the in-plane direction of the thermally conductive insulation sheet according to Reference Example 4.

FIG. 9 shows a SEM photograph of a cross-section perpendicular to the in-plane direction of the thermally conductive insulation sheet precursor according to Reference Example 5.

FIG. 10 shows a SEM photograph of a cross-section perpendicular to the in-plane direction of the thermally conductive insulation sheet according to Reference Comparative Example 1.

FIG. 11 shows a SEM photograph of a cross-section perpendicular to the in-plane direction of the thermally conductive insulation sheet according to Reference Comparative Example 2.

### DESCRIPTION OF EMBODIMENTS

Embodiments of the present invention will be described below.

### <<Heat Dissipation Sheet>>

The heat dissipation sheet of the present disclosure has a structure in which at least two thermally conductive insulation layers are laminated,

wherein the lamination direction of the thermally conductive insulation layers is substantially perpendicular to the thickness direction of the heat dissipation sheet, and

wherein for the entire cross-section perpendicular to the in-plane direction of the heat dissipation sheet, the thermally conductive insulation layer contains 75 to 97% by area of the insulating particles, 3 to 25% by area of the binder resin, and 10% by area or less of the voids.

The heat dissipation sheet of the present disclosure has a relatively high filling ratio (packing ratio) of the insulating particles, and a relatively high thermal conductivity in the thickness direction.

FIG. 1 shows a schematic diagram of a cross-section perpendicular to the plane direction of one embodiment of the heat dissipation sheet in accordance with the present disclosure. As seen in FIG. 1, in the heat dissipation sheet 10, multiple thermally conductive insulation layers A are laminated, and the direction of the lamination is substantially perpendicular to the thickness direction of the heat dissipation sheet. In the heat dissipation sheet 10, adhesive insulation layers B are arranged between the thermally conductive insulation layers A. Incidentally, in FIGS. 1 to 4, the direction D indicates the thickness direction of the heat dissipation sheet, and the direction S indicates the in-plane direction of the heat dissipation sheet.

In the heat dissipation sheet according to the present disclosure, the thermally conductive insulation sheets having high thermal conductivity in the in-plane direction are used as a material of the thermally conductive insulation layers. In the heat dissipation sheet according to the present disclosure, the lamination direction of these thermally conductive insulation layers is substantially perpendicular to the thickness direction of the heat dissipation sheet, and consequently the thermal conductivity of the heat dissipation sheet in the thickness direction is relatively high.

In the present invention, “the lamination direction of the thermally conductive insulation layers is substantially perpendicular to the thickness direction of the heat dissipation sheet” means that the angle between the lamination direction and the thickness direction is 45° to 135°. This angle is preferably 55° to 125°, 65° to 115°, 75° to 105°, 85° to 95°, 87° to 93°, or 89° to 91°.

In the heat dissipation sheet according to the present disclosure, the thermally conductive insulation layers are preferably not only continuously present between one main surface and the other main surface of the heat dissipation sheet, but also present in a manner exposed on one main surface and the other main surface of the heat dissipation sheet. In this case, it is possible to dissipate heat from a member in contact with one surface of the heat dissipation sheet to a member in contact with the other surface of the heat dissipation sheet.

In another embodiment according to the present disclosure, the thermally conductive insulation layers composing the heat dissipation sheet represents at least 50% by volume of the heat dissipation sheet. In this case, since the ratio of the thermally conductive insulation layers having relatively high thermal conductivity in the thickness direction is increased, it is possible to provide a heat dissipation sheet having further improved thermal conductivity in the thickness direction.

Preferably, the ratio of the thermally conductive insulation layers to the heat dissipation sheet may be 55% by volume or more, 60% by volume or more, 65% by volume or more, or 70% by volume or more, and/or 100% by volume or less, less than 100% by volume, less than 99% by volume, less than 98% by volume, less than 95% by volume, less than 90% by volume, less than 80% by volume or less than 75% by volume.

The thickness of the thermally conductive insulation layer is not limited, but the thickness of the thermally conductive insulation layer may be 0.1 μm or more, 1 μm or more, or 10 μm or more, and/or 1000 μm or less, 100 μm or less, 80 μm or less, 70 μm or less, 60 μm or less, or 50 μm or less. The thickness of the thermally conductive insulation layer is, for example, 20 μm to 3000 μm, and preferably 40 μm to 1000 μm.

Although the number of thermally conductive insulation layers included in the heat dissipation sheet is not limited, it may be, for example, 3 or more layers, preferably 11 or more layers, more preferably 21 or more layers. Although the upper limit of the number of thermally conductive insulation layers contained in heat dissipation sheet is not particularly limited, it may be, for example, 1000 layers or less, 500 layers or less, 300 layers or less, or 100 layers or less.

The heat dissipation sheet according to the present disclosure may further comprise an adhesive insulation layer arranged between the at least two thermally conductive insulation layers. When an adhesive insulation layer is arranged between the thermally conductive insulation layers, adhesion between the thermally conductive insulation layers adjacent to each other in the heat dissipation sheet is further improved.

In one aspect of the heat dissipation sheet according to the present disclosure, the heat dissipation sheet further comprises adhesive insulation layers arranged between thermally conductive insulation layers such that the thermally conductive insulation layers and the adhesive insulation layers are alternately laminated.

If the heat dissipation sheet further comprises an adhesive insulation layer, the thermal conductivity in the thickness direction of the heat dissipation sheet obtained is improved when the thickness of the thermally conductive insulation layer is larger than the thickness of the adhesive insulation layer. Therefore, it is preferable that the relative thickness of the thermally conductive insulation layer is as large as possible. For example, the thickness of the thermally conductive insulation layer in the lamination direction is preferably at least twice the thickness of the adhesive insulation layer in the lamination direction. In this case, it is possible to provide a heat dissipation sheet having further improved thermal conductivity in the thickness direction.

When the heat dissipation sheet further comprises an adhesive insulation layer, preferably, the ratio of the thickness of the thermally conductive insulation layer in the lamination direction to the thickness of the adhesive insulation layer in the lamination direction may be 2 or more, 3 or more, 4 or more, or 5 or more, and/or 100 or less, 80 or less, or 50 or less.

When the heat dissipation sheet further comprises an adhesive insulation layer, the respective thickness of the thermally conductive insulation layer and the adhesive insulation layer is not limited, but each of these thicknesses may be 0.1 μm or more, 1 μm or more, or 10 μm or more, and/or may be 1000 μm or less, 100 μm or less, 80 μm or less, 70 μm or less, 60 μm or less, or 50 μm or less, and for example, 20 μm to 3000 μm, preferably 40 μm to 1000 μm, further preferably 0.5 μm to 500 μm, further more preferably 5 μm to 50 μm, and particularly preferably 10 μm to 30 μm. The total of the thermally conductive insulation layers and the adhesive insulation layers is not limited, but is, for example, 3 or more layers, preferably 11 or more layers, and more preferably 21 or more layers. Although the upper limit of the total of the thermally conductive insulation layers and the adhesive insulation layers contained in the heat dissipation sheet is not particularly limited, it may, for example, 2000 layers or less, 1000 layers or less, or 500 layers or less.

### <Thickness>

The thickness of the heat dissipation sheet may vary depending on the heat source, such as a semiconductor element, a power supply, or a light source, which is in contact with the heat dissipation sheet during use thereof. The thickness of the heat dissipation sheet is, however, for example, 0.1 mm to 20 mm, preferably 0.5 mm to 5 mm.

### <Thermally Conductivity in the Thickness Direction>

Preferably, the heat dissipation sheet according to the present disclosure has a thermal conductivity of 20.0 W/(m·K) or more in the thickness direction.

In particular, the thermal conductivity of the heat dissipation sheet in the thickness direction may be 25.0 W/(m·K) or more, 30.0 W/(m·K) or more, 35.0 W/(m·K) or more, or 40.0 W/(m·K) or more, and/or 60.0 W/(m·K) or less, 50.0 W/(m·K) or less, or 45.0 W/(m·K) or less.

Thermal conductivity in the thickness direction of the heat dissipation sheet can be calculated by multiplying all of the thermal diffusivity, specific gravity and specific heat. In other words, it can be calculated by the following:

(Thermal conductivity)=(Thermal diffusivity)×(Specific heat)×(Specific gravity)

Thermal diffusivity in the thickness direction can be obtained by a temperature wave analysis method (a measurement method based on phase-shift of temperature wave). Specific heat can be determined by a differential scanning calorimeter. Further, specific gravity can be determined from the outer dimensions and weight of the heat dissipation sheet.

### <Thermal Conductivity in the In-Plane Direction>

Preferably, the heat dissipation sheet according to the present disclosure has the thermal conductivity of 0.5 W/(m·K) or more in the in-plane direction. More preferably, the thermal conductivity of the heat dissipation sheet in the in-plane direction is 1 W/(m·K) or more, 2 W/(m·K) or more, 5 W/(m·K) or more, or 10 W/(m·K) or more. The heat dissipation sheet according to the present disclosure preferably has the thermal conductivity of 100 W/(m·K) or less in the in-plane direction.

Thermal conductivity in the in-plane direction of the heat dissipation sheet can be calculated by multiplying all of the thermal diffusivity, specific gravity, and specific heat. In other words, it can be calculated by the following:

(Thermal conductivity)=(Thermal diffusivity)×(Specific heat)×(Specific gravity)

The above thermal diffusivity can be measured by an optical alternating current (AC) method, using an optical AC method thermal diffusivity measurement apparatus. Specific heat can be determined by a differential scanning calorimeter. Further, specific gravity can be determined from the outer dimensions and weight of the heat dissipation sheet.

### <Dielectric Breakdown Voltage>

Preferably, the dielectric breakdown voltage of the heat dissipation sheet is 5 kV/mm or more, 8 kV/mm or more, or 10 kV/mm or more. When the dielectric breakdown voltage is 5 kV/mm or more, dielectric breakdown is less likely to occur and the failure of the electronic device is avoided, which is preferable.

The dielectric breakdown voltages of the heat dissipation sheets are measured in accordance with the test standard ASTM D149. A dielectric strength test equipment may be used for the measurement.

### <Relative Permittivity>

In one embodiment of the heat dissipation sheet of the present disclosure, the relative permittivity at 1 GHz is 6 or less. If the relative permittivity at 1 GHz of the heat dissipation sheet is 6 or less, the interference of electromagnetic waves can be avoided, which is preferable.

Preferably, the relative permittivity at 1 GHz is 5.5 or less, 5.3 or less, 5.0 or less, or 4.8 or less. The lower limit of the relative permittivity is not particularly limited, but may be, for example, 1.5 or more, or 2.0 or more.

The relative permittivity in accordance with the present disclosure can be measured by a network analyzer, using a specimen-hole closed type perturbation method of cavity resonance mode.

Hereinafter, each component of the heat dissipation sheet of the present disclosure will be described in more detail.

### <Thermally Conductive Insulation Layer>

The thermally conductive insulation layer of the present disclosure comprises, for the entire cross-section perpendicular to the in-plane direction of the heat dissipation sheet,

75 to 97% by area of the insulating particles,
3 to 25% by area of the binder resin, and
10% by area or less of the voids.

The thermally conductive insulation layer according to the present disclosure has a relatively high thermal conductivity in the in-plane direction. In the heat dissipation sheet according to the present disclosure formed from such a thermally conductive insulation layer, the lamination direction of the thermally conductive insulation layers and the thickness direction of the heat dissipation sheet are substantially perpendicular to each other, and as a result, the heat dissipation sheet has high thermal conductivity in the thickness direction. Further, such a thermally conductive insulation layer has good flexibility, which is a preferable characteristic for example from the viewpoint of mounting the heat dissipation sheet to a semiconductor device.

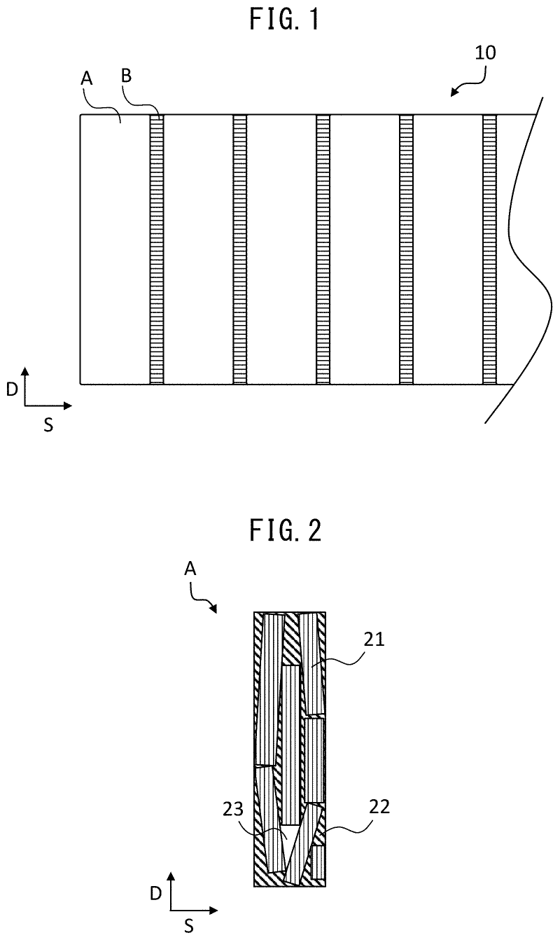

FIG. 2 shows a schematic diagram of a cross section of the thermally conductive insulation layer A composing the heat dissipation sheet 10 according to the present disclosure. In the thermally conductive insulation layer A, the packing ratio of the insulating particles 21 is relatively high because the content of the binder resin 22 is reduced. It is considered that in the heat dissipation sheet 10 formed from such a thermally conductive insulation layer A, due to the high packing ratio of the insulating particles 21, the distance between the particles is relatively small, resulting in high thermal conductivity in the thickness direction D of the heat dissipation sheet. Further, at the same time, it is considered that, due to the reduced content of the binder resin 22, the thermal resistance caused by the resin is suppressed.

Further, in the thermally conductive insulation layer A in FIG. 2, in addition to the content of the binder resin 22 being reduced, voids 23 in the layer are also relatively reduced. It is considered that, in the heat dissipation sheet formed from such a thermally conductive insulation layer A, the packing ratio of the insulating particles 21 is further increased, and as a result, the effect of increasing the thermal conductivity in the thickness direction D is further enhanced.

The thermally conductive insulation layer composing the heat dissipation sheet according to the present disclosure can be obtained for example, by using, as a material, a thermally conductive insulation sheet which is obtained by subjecting a thermally conductive insulation sheet precursor containing insulating particles and a binder resin to a roll press treatment. A thermally conductive insulation sheet precursor shaped into a sheet contains a large amount of bubbles. It is considered that, by compressing the precursor using a roll press method in this state, the insulating particles inside the sheet can be oriented along the in-plane direction of the sheet and the bubbles inside the thermally conductive insulation sheet precursor can be reduced, and as a result, the thermal conductivity in the in-plane direction of the resulting thermally conductive insulation sheet is increased.

FIG. 4 shows a schematic view of a cross-section of a thermally conductive insulation layer X composing a heat dissipation sheet according to the prior art. In the thermally conductive insulation layer X, since the percentage of a binder resin 42 is relatively high and voids 43 between particles are relatively large, the packing ratio of insulating particles 41 is relatively low. It is considered that, in the heat dissipation sheet formed from such a thermally conductive insulation layer X, since the distance between the insulating particles 41 is large, high thermal conductivity in the thickness direction D cannot be obtained.

Incidentally, it is considered that the thermally conductive insulation layer has the same or substantially the same physical properties, for example, the same or substantially the same thermal conductivity and dielectric breakdown voltage as the thermally conductive insulation sheet used as a material for the thermally conductive insulation layer during production of the heat dissipation sheet. Therefore, as for the physical properties of the thermally conductive insulation layer, i.e. thermal conductivity, dielectric breakdown voltage, and relative permittivity, it is possible to refer to the description of the thermally conductive insulation sheet to be described later.

### <Insulating Particle>

The thermally conductive insulation layer according to the present disclosure contains insulating particles.

The thermally conductive insulation layer of the present disclosure comprises, for the entire cross-section perpendicular to the in-plane direction of the heat dissipation sheet, 75 to 97% by area of the insulating particles. When the content of the insulating particles is 75% by area or more, good thermal conductivity is obtained. When the content of the insulating particles is 97% by area or less, increase in viscosity of resin composition is suppressed, thereby ease of molding is ensured.

Preferably, for the entire cross-section perpendicular to the in-plane direction of the heat dissipation sheet, the insulating particles contained in the thermally conductive insulation layer according to the present disclosure may be 80% by area or more, 85% by area or more, or 90% by area or more, and/or 96% by area or less, 95% by area or less, 94% by area or less, 93% by area or less, 92% by area or less, or 91% by area or less.

In the present disclosure, for the entire cross-section perpendicular to the in-plane direction of the heat dissipation sheet, the “% by area” of the insulating particles can be calculated by taking an image of a cross-section of the thermally conductive insulation layer perpendicular to the in-plane direction of the heat dissipation sheet by a scanning electron microscope (SEM) and then by measuring the total area of the insulating particles present in an area in the acquired image.

The insulating particles are not particularly limited and include, for example, boron nitride, aluminum nitride, aluminum oxide, magnesium oxide, silicon nitride, silicon carbide, beryllium oxide, metal silicon particles whose surfaces are insulated, carbon fiber and graphite whose surfaces are coated with an insulating material such as a resin, and polymer fillers. From the viewpoint of thermal conductivity in the thickness direction of the heat dissipation sheet, insulation properties and cost, the insulating particles are preferably boron nitride particles, and in particular hexagonal boron nitride particles. The aspect ratio of the boron nitride particles is preferably 10 to 1000, and more preferably the boron nitride particles has a flat shape.

The average particle size of the insulating particles are preferably from 1 μm to 200 μm, more preferably from 5 μm to 200 μm, still more preferably from 5 μm to 100 μm, and particularly preferably from 10 μm to 100 μm.

Average particle size is a median diameter (a particle diameter for which, when a powder is divided into two by a certain particle diameter, the amount of the particles larger than that particle diameter becomes equal to the amount of the particles smaller than that particle diameter; also generally referred to as D50) measured by a laser diffraction method using a laser diffraction/scattering particle size distribution measurement apparatus.

### (Deformation)

In one advantageous embodiment of the thermally conductive insulation layer according to the present disclosure, the insulating particles comprise flat-shaped particles, i.e., scaly particles or flaky particles, which are deformed.

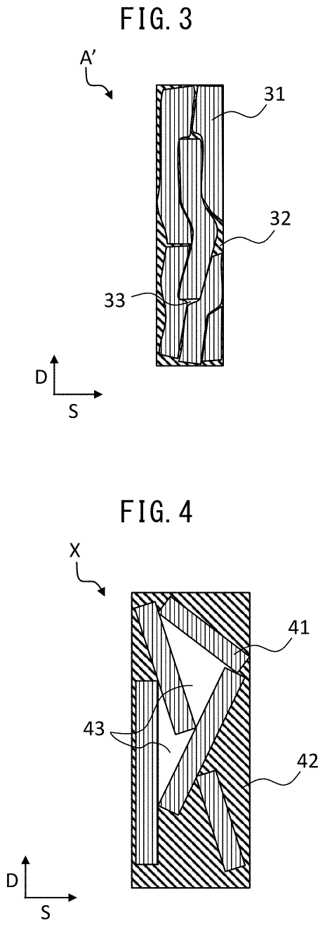

In the heat dissipation sheet having a thermally conductive insulation layer comprising flat-shaped particles which are deformed, the thermal conductivity in the thickness direction is further improved. Without wishing to be bound by theory, one of the reason for this may be that the deformation of the flat-shaped particles further reduces voids within the thermally conductive insulation layer. In general, it is considered that in the case of flat-shaped particles, gaps tend to occur between the particles due to three-dimensional hindrance caused by the shape of the particles. Therefore, conventionally, it has been considered that the percentage of the voids in the sheet (porosity of the sheet) increases when the content of the particles is high. On the other hand, in the thermally conductive insulation layer according to an advantageous embodiment of the present disclosure, for example as shown in the thermally conductive insulation layer (A′) of FIG. 3, the flat-shaped particles 31 are deformed, so that the gaps between the particles are filled, and as a result, the voids 33 are further reduced. It is also considered that, during the roll press treatment for obtaining a thermally conductive insulation sheet which is used as a material for the thermally conductive insulation layer, the deformation of the flat-shaped particles 31 promotes the discharge of air bubbles trapped between the particles to the outside of the sheet and thereby further promotes the reduction of the voids 33.

A method for obtaining the heat dissipation sheet having the thermally conductive insulation layer containing the deformed flat-shaped particles is not particularly limited, but includes for example a method of subjecting a thermally conductive insulation sheet precursor containing insulating particles comprising flat-shaped particles to a roll press treatment in order to obtain a thermally conductive insulation sheet, and producing a heat dissipation sheet from the obtained thermally conductive insulation sheet. In particular, it is considered that the deformation of the particles becomes more remarkable by performing the roll press treatment in a thermally conductive insulation sheet precursor in which the insulating particles comprise flat-shaped particles and the insulating particles are highly packed. Without wishing to be bound by theory, it is considered that in such a method, the shear stress imparted between the flat-shaped particles is relatively high, and as a result, the deformation of the flat-shaped particles is promoted. For example, in the case of the embodiment of FIG. 3, the content of the binder resin 32 is relatively low and the insulating particles are relatively densely packed. It is considered that when the sheet in such a state is subjected to a roll press treatment, since the high shear stress is imparted between the insulating particles, the insulating particles are relatively easily deformed.

Incidentally, even in the conventional thermally conductive insulation layer, the insulating particles may be deformed. However, it is considered that in this case, the degree of deformation is relatively small and not enough to reduce the porosity.

When the insulating particles comprises flat-shaped particles, the flat-shaped particles preferably represent 50% by volume or more per 100 by volume of the entire insulating particles. When the content is 50% by volume or more, good thermal conductivity in the in-plane direction can be ensured. The flat-shaped particles per 100% by volume of the insulating particles are more preferably 60% by volume or more, further preferably 70% by volume or more, still more preferably 80% by volume or more, particularly preferably 90% by volume or more.

### (Flat-Shaped Particle)

The flat-shaped particles may include, for example, hexagonal boron nitride (h-BN) particles.

The average particle size of the flat-shaped particle (in particular boron nitride particle) is, for example, 1 μm or more, preferably 1 μm to 200 μm, more preferably 5 μm to 200 μm, further preferably 5 μm to 100 μm, and particularly preferably 10 μm to 100 μm. When the average particle size is 1 μm or more, the specific surface area of flat-shaped particle is small and compatibility with a resin is ensured, which are preferable. When the average particle size is 200 μm or less, uniformity of thickness of the sheet can be ensured at the time of sheet molding, which is preferable. Flat-shaped particles (in particular Boron nitride particles) may be flat-shaped particles having a single average particle diameter, or a mixture of multiple types of flat-shaped particles having different average particle diameters.

The aspect ratio of the flat-shaped particle is preferably 10 to 1000. When the aspect ratio is 10 or more, an orientation, which is important for higher thermal diffusivity, is ensured, and high thermal diffusivity can be obtained, which is preferable. Further, the aspect ratio of 1000 or less is preferable from the viewpoint of ease of processing, because increase in the viscosity of a composition due to increase in specific surface area is suppressed.

The aspect ratio is a value obtained by dividing the major axis (longitudinal length) of the particle by the thickness of the particle, i.e., major axis/thickness. When the particle is spherical, the aspect ratio is 1, and the aspect ratio increases as the degree of flatness increases.

The aspect ratio can be obtained by measuring the major axis and thickness of the particle at a magnification of 1500 times using a scanning electron microscope and by calculating the major axis/thickness.

When using a flat-shaped particle (in particular boron nitride particles) as the insulating particle, an insulating particle other than the flat-shaped particle may be used in combination with the flat-shaped particle. Even in this case, the flat-shaped particles preferably represent 50% by volume or more per 100% by volume of the entire insulating inorganic particles. If the amount is 50% by volume or more, good thermal conductivity in the in-plane direction can be ensured, which is preferable. The amount of the flat-shaped particles per 100% by volume of the insulating inorganic particles is more preferably 60% by volume or more, further preferably 70% by volume or more, still more preferably 80% by volume or more, and particularly preferably 90% by volume or more.

When using a combination of flat-shaped particles and ceramic particles having isotropic thermal conductivity as the insulating inorganic particles, it is possible to adjust the balance of the thermal conductivity of the thermally conductive insulation layer in the thickness direction of the heat dissipation sheet and the thermal conductivity of the thermally conductive insulation layer in the in-plane direction of the heat dissipation sheet as necessary, which is preferable. Further, among flat-shaped particles, the boron nitride particle is an expensive material. Therefore, for example, it is convenient to use the boron nitride particles in conjunction with an inexpensive material such as metal silicon particles which are insulated by thermal oxidization of the surface. In this case, it is possible to adjust the balance of the cost and thermal conductivity of the thermally conductive insulation layer as necessary, which is preferable.

### (Orientation)

From the viewpoint of obtaining particularly high thermal conductivity in the thickness direction of the heat dissipation sheet, it is preferable that the insulating particles are oriented along the thickness direction of the heat dissipation sheet so that the ratio of the thermal conductivity of the thermally conductive insulation layer in the thickness direction of the heat dissipation sheet to the thermal conductivity of the thermally conductive insulation layer in the lamination direction (stacking direction) is greater than 1. The ratio of the thermal conductivity of the thermally conductive insulation layer in the thickness direction of the heat dissipation sheet to the thermal conductivity of the thermally conductive insulation layer in the lamination direction is preferably 1.5 or more, 2 or more, 3 or more, 4 or more, 5 or more, 6 or more, 7 or more, 8 or more, 9 or more, or 10 or more. The ratio of the thermal conductivity of the thermally conductive insulation layer in the thickness direction of the heat dissipation sheet to the thermal conductivity of the thermally conductive insulation layer in the lamination direction may be, for example, 500 or less, 200 or less, 100 or less, 50 or less, 30 or less, 20 or less, 15 or less, or 12 or less.

When anisotropic flat-shaped particles having a relatively high thermal conductivity in the long axis direction, such as hexagonal boron nitride particles, are contained as insulating particles, it is preferable that, from the viewpoint of obtaining a particularly high thermal conductivity in the thickness direction of the heat dissipation sheet, the long axis direction of the anisotropic flat-shaped particles contained in the thermally conductive insulation layer substantially coincides with the thickness direction of the heat dissipation sheet. Incidentally, when two directions “substantially coincide”, it means that the angle formed by these two directions is, for example, 45° or less, preferably 300 or less, more preferably 15° or less, further preferably 5° or less, or 3° or less, particularly preferably 0°. When flat-shaped boron nitride particles are contained as insulating particles, it is particularly preferable that, from the viewpoint of obtaining a high thermal conductivity in the thickness direction of the heat dissipation sheet, the boron nitride particles are oriented in the direction substantially parallel to the thickness direction of the heat dissipation sheet.

With regard to the substantial coincidence of the long axis direction of the anisotropic flat-shaped particles contained in the thermally conductive insulation layer and the thickness direction of the heat dissipation sheet, it is possible to perform a measurement using an SEM image of the heat dissipation sheet in a cross section perpendicular to the in-plane direction.

When the thermally conductive insulation layer includes boron nitride particles as insulating particles, the degree of orientation of the boron nitride particles contained in the thermally conductive insulation layer is preferably less than 1. The lower the degree of orientation, the more the boron nitride particles are oriented in the same direction as the thickness direction of the heat dissipation sheet. When the degree of orientation of the boron nitride particles contained in the thermally conductive insulation layer is less than 1, since the long axis direction of the boron nitride particles is arranged along the thickness direction of the heat dissipation sheet, it is possible to obtain a further improved thermal conductivity in the thickness direction of the heat dissipation sheet.

Incidentally, it is considered that the degree of orientation of the boron nitride particles in the thermally conductive insulation layer is substantially equal to the degree of orientation of the boron nitride particles in the thermally conductive insulation sheet used for manufacturing the heat dissipation sheet. Therefore, as the degree of orientation of the boron nitride particles in the thermally conductive insulation layer, it is possible to use the degree of orientation of the boron nitride particles in the thermally conductive insulation sheet, which is shown below.

The degree of orientation of the boron nitride particles in the thermally conductive insulation sheet used for manufacturing the heat dissipation sheet is defined with the following equation, by using (002) peak intensity I (002), which corresponds to the c-axis (thickness) direction of the boron nitride particle crystals, and (100) peak intensity I (100), which corresponds to the a-axis (plane) the boron nitride particle crystals, measured by transmission X-ray diffraction on the main surface of the thermally conductive insulation sheet as a measuring surface.

Orientation=I(002)/I(100)

It is more preferable that the degree of orientation of the boron nitride particles in the thermally conductive insulation layer is less than 0.8, less than 0.6, less than 0.4, less than 0.2, or less than 0.1, with substantially zero being particularly preferred. The lower limit of the degree of orientation of the boron nitride particles in the thermally conductive insulation layer is preferably 0 or more, 0.01 or more, or 0.1 or more.

### <Binder Resin>

The thermally conductive insulation layer according to the present disclosure contains a binder resin.

The thermally conductive insulation layer according to the present disclosure contains, for the entire cross-section perpendicular to the in-plane direction of the heat dissipation sheet, 3% to 25% by area of the binder resin. When the content of the binder resin is 25% by area or less, a sufficiently high thermal conductivity can be ensured, and when the content is 3% by area or more, moldability can be ensured. Further, when the content ratio of the binder resin is 3% by area or more, it is considered that the binder resin fills the gap between the insulating particles, etc., thereby reducing the voids.

Preferably, for the entire cross-section perpendicular to the in-plane direction of the heat dissipation sheet, the binder resin contained in the thermally conductive insulation layer according to the present disclosure may be 5% area or more, more than 5% by area, 6% by area or more, 7% by area or more, or 8% by area or more, and/or 24% by area or less, 20% by area or less, 15% by area or less, 12% by area or less, or 10% by area or less. In particular, when the content ratio of the binder resin is 5% by area or more, or greater than 5% by area, it is considered that a sufficient amount of the binder resin is secured to fill gaps between insulating particles, etc., and voids are further reduced.

In the present disclosure, for the entire cross-section perpendicular to the in-plane direction of the heat dissipation sheet, the “% by area” of the binder resin can be calculated by taking an image of the cross-section perpendicular to the in-plane direction of the heat dissipation sheet by SEM, and then by measuring the area of the binder resin present in an area in the obtained image.

The binder resin according to the present disclosure is not particularly limited. Examples of the binder resin include an aramid resin, a polycarbonate resin, an aliphatic polyamide resin, polyvinylidene fluoride (PVDF), a silicone resin, a polyimide resin, a polytetrafluoroethylene (PTFE) resin, a phenol resin, an epoxy resin, a liquid crystal polymer (LCP) resin, a polyarylate (PAR) resin, a polyetherimide (PEI) resin, a polyethersulfone (PES) resin, a polyamideimide (PAI) resin, a polyphenylene sulfide (PPS) resin, a polyether ether ketone (PEEK) resin, and a polybenzoxazole (PBO).

### (Thermal Properties)

From the viewpoint of the thermal properties of the thermally conductive insulation layer, it is preferable that the binder resin has excellent properties in heat resistance and/or flame retardancy. In particular, it is preferable that the melting point or the thermal decomposition temperature of the binder resin is 150° C. or more.

The melting point of the binder resin is measured with a differential scanning calorimeter. The melting point of the binder resin is more preferably 200° C. or higher, still more preferably 250° C. or higher, and particularly preferably 300° C. or higher. The upper limit of the melting point of the binder resin is not particularly limited, but is, for example, 600° C. or less, 500° C. or less, or 400° C. or less.

The thermal decomposition temperature of the binder resin is measured with a differential scanning calorimeter. The thermal decomposition temperature of the binder resin is more preferably 200° C. or more, still more preferably 300° C. or more, particularly preferably 400° C. or more, and most preferably 500° C. or more. The upper limit of the thermal decomposition temperature of the binder resin is not particularly limited, but is, for example, 1000° C. or less, 900° C. or less, or 800° C. or less.

When used for heat dissipation application inside an electronic device for a vehicle, higher heat resistance temperature of the resin material is also required. In the case of a power semiconductor using silicon carbide, heat resistance around 300° C. is required. Therefore, a resin having heat resistance of 300° C. or more can be suitably used for the in-vehicle application, especially for the heat dissipation around the power semiconductor. As an example of such a resin, an aramid resin can be mentioned.

### (Thermoplastic Resin)

From the viewpoint of flexibility and handling property, it is particularly preferable that the binder resin is a thermoplastic binder resin. Since the heat dissipation sheet formed from a thermally conductive insulation layer containing the thermoplastic resin does not require thermal curing at the time of manufacturing, it is excellent in flexibility and can be relatively easily applied to the inside of an electronic device.

In addition, when the binder resin is a thermoplastic binder resin, it is considered that voids in the thermally conductive insulation layer can be further reduced, which is particularly preferable. Without wishing to be bound by theory, it is considered that in the case where a thermoplastic resin is used as the binder resin, the thermoplastic resin is softened by a heat treatment which is applied for example during the roll press treatment at the time of manufacturing the thermally conductive insulation layer, and the discharge of bubbles trapped between the insulating particles is further promoted, and as a result, the effect of reducing voids can be further enhanced.

The thermoplastic resin which can be used as the binder resin according to the present disclosure include an aramid resin, a polycarbonate resin, an aliphatic polyamide resin, polyvinylidene fluoride (PVDF), a thermoplastic polyimide resin, a polytetrafluoroethylene (PTFE) resin, a liquid crystal polymer (LCP) resin, a polyarylate (PAR) resin, a polyetherimide (PEI) resin, a polyethersulfone (PES) resin, a polyamideimide (PAI) resin, a polyphenylene sulfide (PPS) resin, a polyether ether ketone (PEEK) resin, and a polybenzoxazole (PBO) resin.

### (Aramid Resin)

In particular, it is preferable that the binder resin is an aramid resin. When the aramid resin is used as the binder resin, a thermally conductive insulation layer exhibiting further excellent mechanical strength is provided despite having high packing ratio of the insulating particles. Further, from the viewpoint of thermal properties, it is preferable that the binder resin is an aramid resin. The aramid resin has a relatively high thermal decomposition temperature, and the heat dissipation sheet formed from a thermally conductive insulation layer having an aramid resin as the binder resin exhibits excellent flame retardancy.

The aramid resin is a linear polymer compound in which 60% or more of amide bonds are directly bonded to aromatic rings. As the aramid resin, for example, polymetaphenylene isophthalamide and a copolymer thereof, polyparaphenylene terephthalamide and a copolymer thereof can be used, and examples thereof include copolyparaphenylene 3,4′-diphenylether terephthalamide (also referred to as copolyparaphenylene 3, 4′-oxydiphenylene terephthalamide). The aramid resin may be used alone, or multiple aramid resins may be used as a mixture.

### <Void>

The thermally conductive insulation layer of the present disclosure contains, for the entire cross-section perpendicular to the in-plane direction of the heat dissipation sheet, 10% by area or less of voids. When the voids are 10% by area or less, it is possible to obtain good thermal conductivity in the thickness direction of the heat dissipation sheet.

Preferably, for the entire cross-section perpendicular to the in-plane direction of the heat dissipation sheet, the thermally conductive insulation layer of the present disclosure comprises 8% by area or less, 6% by area or less, 4% by area or less, 3% by area or less, 2% by area or less, or 1% by area or less of the voids. Although the lower limit of the void is not particularly limited, for the entire cross-section perpendicular to the in-plane direction of the heat dissipation sheet, the voids may be 0.01% by area or more, 0.1% by area or more, 0.5% by area or more, 0.8% by area or more, or 1.0% by area or more.

In the present disclosure, for the entire cross-section perpendicular to the in-plane direction, the “% by area” of the voids can be calculated by taking an image of the cross-section of the thermally conductive insulation layer perpendicular to the in-plane direction of the heat dissipation sheet by SEM, and then by measuring the area of the voids present in an area in the acquired image.

In the present disclosure, “void” means a gap formed between the elements constituting the thermally conductive insulation layer. Voids are formed, for example, when bubbles, etc., are trapped between the insulating particles, etc., at the time of manufacturing the thermally conductive insulation layer.

### <Parts by Volume>

In another embodiment of the thermally conductive insulation layer according to the present disclosure, the thermally conductive insulation layer according to the present disclosure contains 75 to 97 parts by volume of insulating particles, 3 to 25 parts by volume of a binder resin, and 10 parts by volume or less of voids, based on 100 parts by volume of the thermally conductive insulation layer.

Preferably, the insulating particles contained in the thermally conductive insulation layer according to the present disclosure may be 80 parts by volume or more, 85 parts by volume or more, or 90 parts by volume or more, and/or 96 parts by volume or less, 95 parts by volume or less, 94 parts by volume or less, 93 parts by volume or less, 92 parts by volume or less, or 91 parts by volume or less, based on 100 parts by volume of the thermally conductive insulation layer.

Preferably, the binder resin contained in the thermally conductive insulation layer according to the present disclosure may be 5 parts by volume or more, 6 parts by volume or more, 7 parts by volume or more, or 8 parts by volume or more, and/or 24 parts by volume or less, 20 parts by volume or less, 15 parts by volume or less, 12 parts by volume or less, or 10 parts by volume or less, based on 100 parts by volume of the thermally conductive insulation layer.

Preferably, the thermally conductive insulation layer of the present disclosure contains 8 parts by volume or less, 6 parts by volume or less, 4 parts by volume or less, 3 parts by volume or less, 2 parts by volume or less, or 1 part by volume or less of voids, based on 100 parts by volume of the thermally conductive insulation layer. The lower limit of the content of the voids is not particularly limited, but may be, for example, 0.01 parts by volume or more, 0.1 parts by volume or more, 0.5 parts by volume or more, 0.8 parts by volume or more, or 1.0 parts by volume or more.

When the thermally conductive insulation layer has roughly uniform composition and thickness over the same sample plane, it is considered that the % by area of each component determined in a cross-section perpendicular to the in-plane direction is considered to be substantially equal to the volume ratio of each component in the thermally conductive insulation layer (parts by volume relative to 100 parts by volume of the thermally conductive insulation layer). Therefore, parts by volume of the voids in the thermally conductive insulation layer can be calculated in the same manner as the method described above for the % by area of the voids.

### <Additives>

The thermally conductive insulation layer of the present invention may contain a flame retardant agent, an anti-discoloration agent, a surfactant, a coupling agent, a colorant, a viscosity modifier, and/or a reinforcing material. Further, in order to increase the strength of the sheet, the thermally conductive insulation layer may contain a fibrous reinforcing material. Use of short fibers of an aramid resin as the fibrous reinforcing material is preferable because the heat resistance of the thermally conductive insulation layer is not lowered by the addition of the reinforcing material.

### <Adhesive Insulation Layer>

As a material of the adhesive insulation layer which can be comprised in the heat dissipation sheet of the present disclosure includes an insulating material which can bond thermally conductive insulation layers adjacent to each other. For example, a thermoplastic resin, a thermoplastic elastomer, or a crosslinkable resin may be used.

Examples of the thermoplastic resin include a vinyl acetate resin, polyvinyl acetal, an ethylene vinyl acetate resin, a vinyl chloride resin, an acrylic resin, polyamide, cellulose, α-olefin, and a polyester resin.

Examples of the thermoplastic elastomer include a chloroprene rubber, a nitrile rubber, a styrene butadiene rubber, polysulfide, a butyl rubber, a silicone rubber, an acrylic rubber, an urethane rubber, a silylated urethane resin, and telechelic polyacrylate.

Examples of the crosslinkable resin include an epoxy resin, a phenol resin, and a urethane resin.

In the adhesive insulation layer, it is possible to include an additive such as a curing accelerator, anti-discoloration agent, a surfactant, a coupling agent, a colorant, a viscosity modifier, and a filler, as long as it does not impair the insulating property and the adhesive property.

The adhesive insulation layer may have any form as long as it has adhesiveness. It may be, for example, in the form of a tape, a film, or a sheet.

### <<Manufacturing Method>>

The present disclosure includes a method for manufacturing a heat dissipation sheet according to the present disclosure, comprising:

providing thermally conductive insulation sheets (providing step),

laminating the at least two thermally conductive insulation sheets to obtain a laminate (laminating step), and

slicing the laminate substantially along the lamination direction of the thermally conductive insulation sheets to obtain a heat dissipation sheet (slicing step), wherein for the entire cross-section of the thermally conductive insulation sheet perpendicular to the in-plane direction, the thermally conductive insulation sheet contains 75 to 97% by area of the insulating particles, 3 to 25% by area of the binder resin, and 10% by area or less of the voids.

### <Providing Step>

In the providing step of a method of manufacturing a heat dissipation sheet according to the present disclosure, thermally conductive insulation sheets are provided, wherein for the entire cross-section of the thermally conductive insulation sheet perpendicular to the in-plane direction, the thermally conductive insulation sheet contains 75 to 97% by area of the insulating particles, 3 to 25% by area of the binder resin, and 10% by area or less of the voids.

The thickness of the thermally conductive insulation sheet provided in the providing step is preferably 100 μm or less. Preferably, the thickness of the thermally conductive insulation sheet is 80 μm or less, 70 μm or less, 60 μm or less, or 50 μm or less. Although the lower limit of the thickness of the thermally conductive insulation sheet is not particularly limited, it may be, for example, 0.1 μm or more, 1 μm or more, or 10 μm or more.

### (Thermal Conductivity in the In-Plane Direction)

Preferably, the thermal conductivity of the thermally conductive insulation sheet provided in the providing step is, in the in-plane direction, 30 W/(m·K) or more, 35 W/(m·K) or more, 40 W/(m·K) or more, 45 W/(m·K) or more, 50 W/(m·K) or more, or 55 W/(m·K) or more. Although it is preferable that the thermal conductivity of the thermally conductive insulation sheet provided in the providing step is as high as possible, the thermal conductivity that can normally be achieved is at most 100 W/(m·K) in the in-plane direction.

### (Thermal Conductivity in the Thickness Direction)

Preferably, the thermal conductivity of the thermally conductive insulation sheet provided in the providing step is, in the thickness direction, 0.5 W/(m·K) or more and 5.0 W/(m·K) or less. In particular, the thermal conductivity of the thermally conductive insulation sheet in the thickness direction may be 0.8 W/(m·K) or more, or 1.0 W/(m·K) or more, and/or 4.5 W/(m·K) or less, or 4.0 W/(m·K) or less.

### (Dielectric Breakdown Voltage)

Preferably, the dielectric breakdown voltage of the thermally conductive insulation sheet provided in the providing step is 5 kV/mm or more, and particularly preferably 8 kV/mm or more, or 10 kV/mm or more.

### (Relative Permittivity)

The relative permittivity at 1 GHz of the thermally conductive insulation sheet provided in the providing step is preferably 6 or less, and particularly preferably 5.5 or less, 5.3 or less, 5.0 or less, or 4.8 or less. The lower limit of the relative permittivity is not particularly limited, but may be, for example, 1.5 or more, or 2.0 or more.

From the viewpoint of obtaining a particularly high thermal conductivity in the thickness direction of the heat dissipation sheet, it is preferable that the insulating particles in the thermally conductive insulation sheet are oriented along the in-plane direction of the thermally conductive insulation sheet so that the ratio of the thermal conductivity in the in-plane direction of the thermally conductive insulation sheet to the thermal conductivity in the thickness direction of the thermally conductive insulation sheet is greater than 1. The ratio of the thermal conductivity in the in-plane direction of the thermally conductive insulation sheet to the thermal conductivity in the thickness direction of the thermally conductive insulation sheet is preferably 1.5 or more, 2 or more, 3 or more, 4 or more, 5 or more, 6 or more, 7 or more, 8 or more, 9 or more, or 10 or more. The ratio of the thermal conductivity in the in-plane direction of the thermally conductive insulation sheet to the thermal conductivity in the thickness direction of the thermally conductive insulation sheet may be, for example, 500 or less, 200 or less, 100 or less, 50 or less, 30 or less, 20 or less, 15 or less, or 12 or less.

When anisotropic flat-shaped particles having a relatively high thermal conductivity in the long axis direction, such as hexagonal boron nitride particles, are contained as the insulating particles, it is preferable from the viewpoint of obtaining a particularly high thermal conductivity in the thickness direction of the heat dissipation sheet that the long axis direction of the anisotropic flat-shaped particles in the thermally conductive insulation sheet substantially coincides with the in-plane direction of the thermally conductive insulation sheet. When flat-shaped boron nitride particles are contained as insulating particles, it is particularly preferable from the viewpoint of obtaining a high thermal conductivity in the thickness direction of the heat dissipation sheet that the boron nitride particles are oriented in a direction substantially parallel to the main surface of the thermally conductive insulation sheet.

With regard to the substantial coincidence of the long axis direction of the anisotropic flat-shaped particles contained in the thermally conductive insulation sheet and the in-plane direction of the thermally conductive insulation sheet, it is possible to conduct a measurement using an SEM image of the thermally conductive insulation sheet in a cross section perpendicular to the in-plane direction.

When the thermally conductive insulation sheet contains boron nitride particles as insulating particles, the degree of orientation of the boron nitride particles contained in the thermally conductive insulation sheet is preferably less than 1. The lower the degree of orientation, the more the boron nitride particles are oriented in the same direction as the in-plane direction of the thermally conductive insulation sheet. When the degree of orientation of the boron nitride particles contained in the thermally conductive insulation sheet is less than 1, the long axis direction of the anisotropic flat-shaped particles are oriented along the in-plane direction of the thermally conductive insulation sheet, which makes it possible to obtain a further improved thermal conductivity in the thickness direction of the heat dissipation sheet when manufacturing the heat dissipation sheet according to the manufacturing method of the present disclosure.

The degree of orientation of the boron nitride particles in thermally conductive insulation sheet is defined by the following equation, using (002) peak intensity I (002) which corresponds to the c-axis direction (thickness direction) of the boron nitride particle crystals, and (100) peak intensity I (100) which corresponds to the a-axis direction (plane direction) of the boron nitride particle crystals, measured by transmission X-ray diffraction on the main surface of the thermally conductive insulation sheet as a measuring surface.

Orientation=I(002)/I(100)

It is more preferable that the degree of orientation of the boron nitride particles in the thermally conductive insulation sheet is less than 0.8, less than 0.6, less than 0.4, less than 0.2, or less than 0.1, with substantially zero being particularly preferred. The lower limit of the degree of orientation of the boron nitride particles in the thermally conductive insulation sheet is preferably 0 or more, 0.01 or more, or 0.1 or more.

### (Manufacturing Method of Thermally Conductive Insulation Sheet)

The thermally conductive insulation sheet according to the present disclosure can be provided for example in accordance with the manufacturing method of the thermally conductive insulation sheet comprising the following steps:

a mixing step of mixing insulating particles, a binder resin, and a solvent to obtain a slurry,

a shaping step of shaping the slurry after the mixing step into a sheet and drying the shaped slurry to form a thermally conductive insulation sheet precursor, and

a roll press step of subjecting the thermally conductive insulation sheet precursor to a roll press treatment.

### (Mixing Step)

In the mixing step of the manufacturing method of the thermally conducive insulation sheet according to the present disclosure, insulating particles, a binder resin, and a solvent are mixed to obtain a slurry.

Regarding the insulating particles and the binder resin, reference can be made to the above descriptions relating to the thermally conductive insulation layer. The insulating particles preferably comprise flat-shaped particles, in particular 50% by volume or more of boron nitride particles with respect to 100% by volume of the insulating particles. When the insulating particles include boron nitride particles, the amount of boron nitride particles per 100% by volume of the insulating inorganic particles is more preferably 60% by volume or more, further preferably 70% by volume or more, still more preferably 80% by volume or more, and particularly preferably 90% by volume or more.

In the mixing step, a flame retardant agent, an anti-discoloration agent, a surfactant, a coupling agent, a colorant, a viscosity modifier, and/or a reinforcing material may be optionally added. In order to increase the strength of the sheet, a fibrous reinforcing material may be added.

### (Solvent)

As the solvent, a solvent capable of dissolving the binder resin can be used. For example, when an aramid resin is used as the binder resin, 1-methyl-2-pyrrolidone, N,N-dimethylacetamide, or dimethyl sulfoxide can be used.

### (Mixing)

For mixing the insulating particles, the binder resin, and the solvent, a general mixing apparatus, such as a paint shaker, a bead mill, a planetary mixer, a stirring type disperser, a rotation-revolution stirring mixer, a three-roll mill, a kneader, a single-shaft or two-shaft kneader, etc., can be used.

### (Shaping Step)

In the shaping step of the manufacturing method of the thermally conductive insulation sheet according to the present disclosure, the slurry after the mixing step is shaped into a sheet and dried to form a thermally conducive insulation sheet precursor.

### (Shaping)

In order to shape the slurry after the mixing step into a sheet, a known method can be used, such as a method of applying a resin composition on a release film by a coater, as well as an extrusion molding, an injection molding, or a laminate molding.

### (Drying)

Drying may be carried out by a known method. For example, the slurry applied on a substrate may be dried, and then, after the shaped slurry is peeled off from the substrate in water, a further drying may be performed. The drying temperature may be, for example, 50° C. to 120° C., and the drying time may be, for example, 10 minutes to 3 hours.

### (Roll Press Step)

In the roll press step of the manufacturing method of the thermally conducive insulation sheet according to the present disclosure, the thermally conductive insulation sheet precursor is subjected to a roll press treatment.

### (Roll Press)

The roll press treatment may be performed by a known method, and for example, the thermally conductive insulation sheet precursor may be pressed by a calendar roll machine. The pressure applied to a thermally conductive insulation sheet precursor during the roll press step is preferably 400 to 8000 N/cm in linear pressure. When the linear pressure is 400 N/cm or more, the deformation of the insulating particles is promoted, and the discharge of air bubbles to the outside of the sheet becomes remarkable. When the linear pressure is 8000 N/cm or less, the insulating particles are sufficiently deformed and densely packed and voids inside the sheet are reduced while the breakage of the insulating particles is prevented. It is preferable that the diameter of a roll used in the roll press treatment is, for example, 200 mm to 1500 mm.

### (Heating Temperature)

During the roll press treatment, it is preferable to heat the thermally conductive insulation sheet precursor. Suitable heating temperature can be determined depending on the conditions such as the type of the binder resin to be used, etc. When an aramid resin is used as the binder resin, the heating temperature is preferably 100° C. to 400° C. By using the heating temperature of 100° C. or more, the binder resin is easily softened, and the effect of filling the gaps between the insulating particles by the roll press treatment is easily obtained. By using the heating temperature of 400° C. or less, the decrease in the strength of the binder resin due to the thermal history less occurs.

### (Flat-Shaped Particle)

In an embodiment of the manufacturing method according to the present disclosure, the insulating particles contained in the slurry include flat-shaped particles. In this case, it is considered that the voids in the sheet are further reduced through the deformation of the particles by the roll press treatment. Without wishing to be bound by theory, it is considered that the flat-shaped particles may be susceptible to deformation as compared with, for example, spherical particles. Particularly, the insulating particles preferably contain 50% by volume or more of flat-shaped particles, in particular 50% by volume or more of boron nitride particles, based on 100% by volume of the insulating particles. The flat-shaped particles, in particular the boron nitride particles, are more preferably 60% by volume or more, further preferably 70% by volume or more, still more preferably 80% by volume or more, and particularly preferably 90% by volume or more, based on 100% by volume of the insulating particles.

In another embodiment of the manufacturing method of the thermally conductive insulation sheet according to the present disclosure, the insulating particles comprise flat-shaped particles and the slurry comprises 75 to 97 parts by volume of insulating particles and 3 to 25 parts by volume of a binder resin, based on 100 parts by volume of the total of the insulating particles and the binder resin. It is considered that when the thermally conductive insulation sheet precursor formed from such a slurry is subjected to a roll press treatment, the deformation of the flat-shaped particles is further promoted, and as a result, the voids of the thermally conductive insulation sheet are further reduced. Without wishing to be bound by theory, it is considered that when the content of the insulating particles in the thermally conductive insulation sheet precursor is relatively high, the shear stress exerted between the insulating particles during the roll press treatment is relatively high due to the relatively close distance between the insulating particles, and as a result, the deformation of the insulating particles is promoted. In addition, it is considered that the flat-shaped insulating particles deform so as to fill the gap in the sheet, and as a result, the percentage of the voids in the sheet is further reduced.

### <Laminating Step>

In the laminating step according to the manufacturing method of the heat dissipation sheet according to the present disclosure, at least two thermally conductive insulation sheets are laminated to obtain a laminate.

In the laminating step, multiple thermally conductive insulation sheets may be laminated in the thickness direction. For example, multiple thermally conductive insulation sheets cut to an appropriate size may be laminated to obtain a laminate.

Further, in the laminating step, the thermally conductive insulation sheet may be folded or wound. For example, it is possible to obtain a laminate of the thermally conductive insulation sheets, by winding a thermally conductive insulation sheet on a plate material to form a first layer, then by winding a new layer thereon to form a second layer, and then by repeating the process until the desired number of layers are obtained. Further, a laminate may be manufactured by forming multiple laminates in this manner and then stacking these laminates.

In the laminating step, after laminating the thermally conductive insulation sheets, a heat treatment may be further performed. By further performing the heat treatment, adhesion between each of the thermally conductive insulation sheets in the resulting laminate is further improved. The temperature of the heat treatment may be appropriately selected in accordance with the conditions such as the type of the binder resin contained in the thermally conductive insulation sheet, but the temperature of the heat treatment is preferably a temperature which promotes fusion between the thermally conductive insulation sheets.

In the laminating step, when laminating the thermally conducive insulation sheets, it is possible to apply a solvent on the thermally conductive insulation sheet. Adhesion between adjacent thermally conductive insulation sheets can be further improved by applying a solvent to dissolve a part of the binder resin constituting the thermally conductive insulation sheet. In this case, the solvent is no particularly limited, and a known solvent can be used depending on the type of the binder resin contained in the thermally conductive insulation sheet, etc.

### (Adhesive Insulation Material)

In the laminating step, when laminating the thermally conductive insulation sheet, an adhesive insulation material may be arranged between the thermally conductive insulation sheets.

In the laminating step, for example, when laminating the thermally conductive insulation sheets, it is possible to arrange adhesive insulation materials between the thermally conducive insulation sheets, in order to obtain a laminate in which the thermally conductive insulation layers and the adhesive insulation layers are arranged alternately.

In an exemplary laminating step in which an adhesive insulation material is arranged, it is possible to perform the lamination by arranging an adhesive insulation material on the surface of a thermally conductive insulation sheet by coating or boding, etc., then by placing another thermally conductive insulation sheet thereon, and then by repeating these operations.

Alternatively, it is possible to perform the laminating step by winding a thermally conductive insulation sheet on a plate material to obtain a first layer, then by applying thereto or bonding thereon a material constituting an adhesive insulation layer, then by winding another thermally conductive insulation sheet thereon to form a second layer, and then by repeating these operations until the desired number of layers are obtained.

The adhesive insulation material may be in any form, such as a liquid form, a powder form, or a sheet form. The arrangement of the adhesive insulation material on the thermally conductive insulation sheet may be performed by any method, including coating, attachment, or spraying. For example, it is possible to apply or spray an adhesive insulation material in the form of a layer. It is also possible to dissolve an adhesive insulation material in a suitable solvent to perform coating, etc. In this case, a suitable solvent may be selected depending on the type of the adhesive insulation material, etc. Hexane is preferably used as the solvent.

As for the adhesive insulation material, reference may be made to the description of the adhesive insulation layer described above.

### (Press)

In the laminating step, the laminate having at least two thermally conductive insulation sheets and optional adhesive insulation materials may be subjected to a press treatment.

A method for performing the press treatment is not particularly limited, and it may be, for example, a hot press. The hot press includes a vacuum hot press using a vacuum hot press machine. The temperature of the hot press can be appropriately selected based on the binder resin constituting the thermally conductive insulation sheet and optional adhesive insulation material. The hot press may be performed, for example, under vacuum conditions (e.g., 0 to 10 Pa), under temperature conditions of 100° C. to 300° C., and for 1 minute to 10 hours. The hot press may be performed, for example, under a press condition of 0.1 MPa to 1000 MPa, 0.2 MPa to 500 MPa, 0.5 MPa to 250 MPa, 1 MPa to 100 MPa, 2 MPa to 50 MPa. or 5 MPa to 25 MPa.

### <Slicing Step>

In the slicing process according to the manufacturing method of the heat dissipation sheet according to the present disclosure, the laminate is sliced substantially along the lamination direction of the thermally conductive insulation sheets to obtain a heat dissipation sheet.

In the slicing step, slicing is performed so that the thickness direction of the heat dissipation sheet obtained by slicing is substantially perpendicular to the lamination direction of the thermally conductive insulation sheet constituting the heat dissipation sheet.

The slicing may be performed by a known method such as a multi-blade method, a laser processing method, a water jet method, a knife processing method, a fixed abrasive wire saw method, a free abrasive wire saw method, etc. Further, the slicing may be performed using a common blade or cutting tool or a cutting machine, such as a cutter knife, a razor, or a Thomson blade, having a sharp blade. By using a cutting tool or fixed abrasive wire saw, etc., having a sharp blade, it is possible to suppress the disturbance of the particle orientation near the surface of the heat dissipation sheet obtained after slicing, and a relatively thin heat dissipation sheet can be easily obtained.

The thickness of the heat dissipation sheet obtained by the slicing is not particularly limited, but is, for example, 0.1 mm to 20 mm, and preferably 0.5 mm to 5 mm.

### EXAMPLES

The invention according to the present disclosure will be explained in the following by way of Examples.

The measurements were performed by the following method.

### (1) Thermal Conductivity

Thermal conductivity in the thickness direction of the heat dissipation sheet, and the thermal conductivity in the in-plane direction of the thermally conductive insulation sheet were each calculated by multiplying all of the thermal diffusivity, specific gravity and specific heat.

(Thermal conductivity)=(Thermal diffusivity)×(Specific heat)×(Specific gravity)

The thermal diffusivity in the thickness direction of the heat dissipation sheet was determined by the temperature wave analysis method. Ai-Phase mobile M3 type1 manufactured by ai-Phase Co., Ltd was used as the measuring device. The thermal diffusivity in the in-plane direction of the thermally conductive insulation sheet was obtained by the periodic heating radiation thermometry. A LaserPIT manufactured by ADVANCE RIKO, Inc. was used as the measuring device. Specific heat was determined using a differential scanning calorimeter (DSCQ10 from TA Instruments). Specific gravity was determined from the outer dimensions and weight of the heat dissipation sheet and the thermally conductive insulation sheet.

### (2) Dielectric Breakdown Voltage

The dielectric breakdown voltage of the insulation sheet was measured in accordance with the test standard ASTM D 149. The dielectric strength test equipment made by Tokyo Transformer Co. was used as the measurement equipment.

### (3) Average Particle Size: Aspect Ratio

For the average particle size of the boron nitride particles, measurement was performed using a laser diffraction/scattering type particle size distribution measurement apparatus (MT3000, manufactured by MicrotracBEL Corp.) under the measurement time of 10 seconds and with single measurement to obtain a D50 value in the volume distribution. The aspect ratio of the boron nitride particles was calculated from the major axis and thickness of the particles measured at a magnification of 1500 times using a scanning electron microscopy (TM3000 type Miniscope manufactured by Hitachi High-Tech Corporation).

### Example 1

### <Manufacturing a Heat Dissipation Sheet>

### (Manufacturing a Thermally Conductive Insulation Sheet)

To 450 parts by volume of 1-methyl-2-pyrrolidone, 10 parts by volume of aramid resin “Technora” as a binder resin was dissolved, then 90 parts by volume of plate-shaped boron nitride particles “PT110” (manufactured by Momentive, mean particle diameter of 45 micrometers, aspect ratio of 35) were added, and then the mixture was stirred for 60 minutes with a three-one motor stirrer while being heated to 80° C., in order to obtain a uniform slurry.

The resulting slurry was applied onto a glass plate using a bar coater having a clearance of 0.35 mm to form a sheet, and dried at 70° C. for 1 hour. Thereafter, the shaped slurry was peeled off from the glass plate in water and then dried at 100° C. for 1 hour to obtain a thermally conductive insulation sheet precursor having a thickness of 120 μm. The resulting thermally conductive insulation sheet precursor was subjected to the compression treatment with a calender roll machine under the conditions of temperature of 270° C. and linear pressure of 4000 N/cm, in order to obtain a thermally conductive insulation sheet having the thickness of 55 μm. The thermal conductivity in the in-plane direction of this thermally conductive insulation sheet was 40 W/(m·K).

### (Lamination)

The obtained thermally conductive insulation sheet was cut into the dimension of 20 mm length×20 mm width. The thermally conducive insulation sheets and adhesive insulation layers were alternately laminated, wherein the adhesive insulation layers being obtained by spray-coating a mixture liquid containing styrene butadiene rubber (SBR) dissolved in isohexane and cyclohexane. A laminate having the thickness of 28 mm was obtained by laminating 400 sheets in total of the thermally conductive insulation sheets. The thickness of the adhesive insulation layers was 15 μm on average.

### (Cut)

The obtained laminate was cut twice at 1 mm intervals with a blade of a razor substantially perpendicular to the main surface of the thermally conductive insulation sheets, in order to obtain a heat dissipation sheet having the dimension of 28 mm length×20 mm width×1 mm thickness.

### (Measurement)

Thermal conductivity in the thickness direction of the heat dissipation sheet obtained was 34 W/(m·K), and the dielectric breakdown voltage thereof was 12 kV.

### Example 2

### <Manufacturing a Heat Dissipation Sheet>

### (Manufacturing a Thermally Conductive Insulation Sheet)

To 450 parts by volume of 1-methyl-2-pyrrolidone, 14 parts by volume of aramid resin “Technora” as a binder resin was dissolved, then 86 parts by volume of plate-shaped boron nitride particles “HSP” (manufactured by Dandong Chemical Engineering Institute Co., mean particle diameter of 40 micrometers) were added, and then the mixture was stirred for 60 minutes with a three-one motor stirrer while being heated to 80° C., in order to obtain a uniform slurry.

The resulting slurry was applied onto a glass plate using a bar coater having a clearance of 0.35 mm to form a sheet, and dried at 70° C. for 1 hour. Thereafter, the shaped slurry was peeled off from the glass plate in water and then dried at 100° C. for 1 hour to obtain a thermally conductive insulation sheet precursor having the thickness of 120 μm. The resulting thermally conductive insulation sheet precursor was subjected to the compression treatment by a calender roll machine under the conditions of temperature of 220° C. and linear pressure of 6000 N/cm, in order to obtain a thermally conductive insulation sheet having the thickness of 50 μm. The thermal conductivity in the in-plane direction of the thermally conductive insulation sheet was 50 W/(m·K).

### (Lamination)

The obtained thermally conductive insulation sheet was cut to the dimension of 100 mm length×100 mm width. One hundred sets (200 layers in total) of the thermally conductive insulation sheets and film-shaped hot-melt type adhesive “G-13” (manufactured by Kurashiki Spinning Co., Ltd.: polyester-based adhesive, thickness of 30 μm) as adhesive insulation layers were alternately laminated. After the lamination, the laminate was held at 155° C. for 5 minutes under 3 MPa pressure and at a vacuum degree of 2 kPa using a vacuum hot press machine, in order to obtain a laminate having the thickness of 8 mm.

### (Cut)

The obtained laminate was cut twice at 1 mm intervals with a blade of a razor substantially perpendicular to the main surface of the thermally conductive insulation sheet, in order to obtain a heat dissipation sheet having the dimension of 100 mm length×8 mm width×1 mm thickness.

### (Measurement)

Thermal conductivity in the thickness direction of the obtained heat dissipation sheet was 31 W/(m·K).

### Reference Examples 1-5, Reference Comparative Examples 1-2

The thermally conductive insulation sheets according to Reference Examples 1 to 4, the thermally conductive insulation sheets according to Reference Comparative Examples 1 to 2, and the thermally conductive insulation sheet precursor according to Reference Example 5 were prepared. The properties of the obtained thermally conductive insulation sheets and thermally conductive insulation sheet precursor were measured. The measurements were performed as described below.

### (1) Thermal Conductivity

Thermal conductivity was calculated by multiplying all of the thermal diffusivity, specific gravity and specific heat, for the thickness direction and the in-plane direction, respectively.

(Thermal conductivity)=(Thermal diffusivity)×(Specific heat)×(Specific gravity)

The thermal diffusivity in the thickness direction was determined by the temperature wave analysis method. Ai-Phase mobile M3 type1 manufactured by ai-Phase Co., Ltd was used as the measuring device. The thermal diffusivity in the in-plane direction was determined by the optical AC (optical alternating current) method, and LaserPIT manufactured by ADVANCE RIKO. Inc. was used as the measuring device. Specific heat was determined using a differential scanning calorimeter (DSCQ10 from TA Instruments). Specific gravity was determined from the outer dimensions and weight of the insulation sheet.

### (2) Dielectric Breakdown Voltage

The dielectric breakdown voltage was measured in accordance with the test standard ASTM D149. The dielectric strength test equipment manufactured by Tokyo Transformer Co. was used as the measurement equipment.

### (3) Average Particle Size, Aspect Ratio

(i) As an average particle size, a D50 value in the volume distribution was obtained by using a laser diffraction/scattering type particle size distribution measurement apparatus (MT3000, manufactured by MicrotracBEL Corp.), with measurement time of 10 seconds and with a single measurement.
(ii) The aspect ratio was calculated from the major axis and thickness of a particle measured at a magnification of 1500 times using a scanning electron microscope (TM3000 type Miniscope, manufactured by Hitachi High-Tech Corporation).

### (Bulk Density)

Bulk density was calculated for a thermally conductive insulation sheet cut to 50 mm square, from the mass measured using a precision electronic balance, the thickness measured by a micrometer, and the sheet area measured by a caliper.

### (Percentage of Voids (% by Area))

Percentage of voids (porosity) was obtained by imaging a cross-section of a sheet perpendicular to the in-plane direction at a magnification of 3000 times with a scanning electron microscope (SEM), and by calculating the area of the voids present in an area of the cross-sectional image obtained.

### (Degree of Orientation)

The degree of orientation of the boron nitride particles was evaluated from peak intensity ratio of the transmission X-ray diffraction (XRD, NANO-Viewer manufactured by Rigaku Corporation) on a main surface of an insulation sheet as the measuring surface. The degree of orientation was defined by the following formula, using (002) peak intensity I (002) corresponding to the c-axis (thickness) direction of the boron nitride crystal and (100) peak intensity I (100) corresponding to the a-axis (plane).

(Orientation of Boron Nitride Particles)=I(002)/I(100)

It is considered that the lower the value of the degree of orientation, the more the boron nitride particles are oriented in the same direction as the in-plane direction of a sheet.

### (Relative Permittivity)

The relative permittivity at 1 GHz of a thermally conductive insulation sheet was measured by a network analyzer (E8361A, manufactured by KEYCOM Corporation) in accordance with a specimen-hole closed type perturbation method of cavity resonance mode.

### Reference Example 1 (Ref.Ex.1)

To 350 parts by volume of 1-methyl-2-pyrrolidone (manufactured by FUJIFILM Wako Pure Chemical Corporation), 5 parts by volume of aramid resin “Technora” (copolyparaphenylene-3,4′-diphenylether terephthalamide, manufactured by Teijin Limited) as a binder resin and 2 parts by volume of anhydrous calcium chloride (manufactured by FUJIFILM Wako Pure Chemical Corporation) as a stabilizer of a dissolved resin were dissolved, and then 95 parts by volume of scaly boron nitride particles “HSL” (manufactured by Dandong Chemical Engineering Institute Co., mean particle diameter of 30 μm) as insulating particles were added, and the mixture was mixed for 10 minutes with a rotation-revolution mixer to obtain a slurry. The obtained slurry was applied onto a glass plate using a bar coater with a clearance of 0.14 mm for shaping, and dried at 115° C. for 20 minutes. Thereafter, after immersed and desalted in ion-exchanged water for 1 hours, the slurry shaped into a sheet was peeled off from the glass plate in water. The peeled sheet was dried at 100° C. for 30 minutes to obtain a thermally conductive insulation sheet precursor having the thickness of 100 μm. The resulting thermally conductive insulation sheet precursor was subjected to the compression treatment by a calender roll machine under the conditions of temperature 280° C. and linear pressure of 4000 N/cm, to obtain a flexible thermally conductive insulation sheet having the thickness of 37 μm (the thermally conductive insulation sheet according to Reference Example 1).

### Reference Example 2 (Ref.Ex.2)

A thermally conductive insulation sheet having the thickness of 27 μm (the thermally conductive insulation sheet of Reference Example 2) was obtained in the same manner as in Reference Example 1, except that 8 parts by volume of the aramid resin and 92 parts by volume of the scaly boron nitride particles were used.

### Reference Example 3 (Ref.Ex.3)

To 450 parts by volume of 1-methyl-2-pyrrolidone (manufactured by FUJIFILM Wako Pure Chemical Corporation), 10 parts by volume of aramid resin “Technora” as a binder resin was dissolved, and then 90 parts by volume of scaly boron nitride particles “PT110” (manufactured by Momentive, with average particle diameter of 45 μm and aspect ratio of 35) as insulating particles were added, and the mixture was stirred for 60 minutes by a Three-One Motor stirrer while heating to 80° C., in order to obtain a uniform slurry.

The obtained slurry was applied onto a glass plate using a bar coater with a clearance of 0.28 mm to form a sheet, and dried at 70° C. for 1 hours. Thereafter, the shaped slurry was peeled off from the glass plate in water and then dried at 100° C. for 1 hours to obtain a thermally conductive insulation sheet precursor having the thickness of 100 μm. The resulting thermally conductive insulation sheet precursor was subjected to the compression treatment by a calender roll machine under the conditions of temperature 270° C. and linear pressure of 4000 N/cm, to obtain a thermally conductive insulation sheet having the thickness of 48 μm (the thermally conductive insulation sheet according to Reference Example 3).

### Reference Example 4 (Ref.Ex.4)

A thermally conductive insulation sheet having the thickness of 25 μm (the thermally conductive insulation sheet according to Reference Example 4) was obtained in the same manner as in Reference Example 1, except that 20 parts by volume of the aramid resin and 80 parts by volume of the scaly boron nitride particles were used.

### Reference Comparative Example 1 (Ref.Comp.1)

A thermally conductive insulation sheet precursor having the thickness of 100 μm was prepared in the same manner as in Reference Example 1, except that 8 parts by volume of the aramid resin and 92 parts by volume of the scaly boron nitride particles were used. The thermally conductive insulation sheet precursor was subjected to a hot press treatment using a vertical vacuum press apparatus at 280° C. in a vacuum atmosphere of 5 Pa under a load of 5 tons (20 MPa) for 2 minutes (after starting the press, 40 minutes for raising the temperature, 2 minutes for holding, and 70 minutes for decreasing the temperature), to obtain a thermally conductive insulation sheet having the thickness of 42 μm (the thermally conductive insulation sheet according to Reference Comparative Example 1).

### Reference Comparative Example 2 (Ref.Comp.2)

A thermally conductive insulation sheet having the thickness of 26 μm (the thermally conductive insulation sheet according to Reference Comparative Example 2) was obtained in the same manner as in Reference Example 1, except that 30 parts by volume of the aramid resin and 70 parts by volume of the scaly boron nitride particles were used.

### Reference Example 5 (Ref.Ex.5)

A thermally conductive insulation sheet precursor having the thickness of 100 μm (the thermally conductive insulation sheet precursor according to Reference Example 5) was obtained in accordance with the same method as in Reference Example 1 up to the step of drying at 100° C. for 30 minutes, except that 8 parts by volume of the aramid resin and 92 parts by volume of the scaly boron nitride particles were used.

### <<Evaluation of Properties>>

The measurement results performed for Reference Examples 1 to 4, Reference Comparative Examples 1 to 2, and Reference Example 5 are shown in Table 1. Incidentally, regarding Reference Example 5, a cross-section perpendicular to the in-plane direction cannot be defined due to large voids, and therefore an evaluation in a cross-section cannot be performed. Therefore, % by area of insulating particles, a binder resin and voids for Reference Example 5 are denoted as “unable to be measured”.

### [Table 1]

TABLE 1

| | | | | | Ref. | Ref. | Ref. | Ref. | Ref. | Ref. | Ref. |
|---|---|---|---|---|---|---|---|---|---|---|---|
| | | | | Unit | Ex. 1 | Ex. 2 | Ex. 3 | Ex. 4 | Comp. 1 | Comp. 2 | Ex. 5 |
| Composition | insulating | flat- | boron nitride | Parts by | — | — | 90 | — | — | — | — |
| | particles | shaped | “PT110” | volume | | | | | | | |
| | | | boron nitride | Parts by | 95 | 92 | — | 80 | 92 | 70 | 92 |
| | | | “HSL” | volume | | | | | | | |

| | | | | | | | | | |
|---|---|---|---|---|---|---|---|---|---|
| binder | aramid resin | parts by | 5 | 8 | 10 | 20 | 8 | 30 | 8 |
| resin | “Technora” | volume | | | | | | | |

| | | | | | | | | | |
|---|---|---|---|---|---|---|---|---|---|
| stabilizer | Anhydrous calcium | parts by | 2 | 2 | — | 2 | 2 | 2 | 2 |
| | chloride | volume | | | | | | | |

| | solvent | parts by | 350 | 350 | 450 | 350 | 350 | 350 | 350 |
|---|---|---|---|---|---|---|---|---|---|
| | | volume | | | | | | | |
| manufacturing method (press) | | — | roll | roll | roll | roll | vertical vaccum | roll | — |
| | | | press | press | press | press | hot press | press | |

| | | | | | | | | | |
|---|---|---|---|---|---|---|---|---|---|
| Characteristics | thermal conductivity (in-plane | W/m − K | 51 | 60 | 40 | 30 | 14 | 26 | 5 |
| | direction) | | | | | | | | |
| | thermal conductivity (thickness | W/m − K | 2.6 | 1.2 | 3.5 | 2.0 | 0.8 | 1.3 | 1.0 |
| | direction) | | | | | | | | |
| | dielectric breakdown voltage | kV/mm | — | 60 | 75 | — | — | — | — |
| | bulk density | g/cm³ | 2.03 | 2.02 | 2.11 | 2.04 | 1.50 | 1.88 | 0.60 |
| | insulating particles | % by area | (92.6) | (91.0) | (88.6) | (79.7) | (77.2) | (68.9) | (※) |
| | binder resin | % by area | (4.9) | (7.9) | (9.8) | (19.9) | (6.7) | (29.5) | (※) |
| | voids | % by area | 2.5 | 1.1 | 1.6 | 0.4 | 16.1 | 1.6 | (※) |
| | orientation | — | — | 0.74 | — | — | 0.40 | — | 0.91 |
| | relative permittivity (1 GHz) | — | — | 4.74 | — | — | — | — | — |

(※) unable to be measured

As can be seen in Table 1, relatively high thermal conductivity in the in-plane direction was observed in the thermally conductive insulation sheets according to Reference Examples 1 to 4 which contains, for the entire cross-section perpendicular to the in-plane direction, 75 to 97% by area of insulating particles, 3 to 25% by area of binder resin, and 10% by area or less of voids. As described above, % by area of the binder resin and % by area of the insulating particles substantially correspond to parts by volume of the binder resin and parts by volume of the insulating particles, respectively, and in Table 1, “% by area” estimated in this manner is shown in “( )”.

Incidentally, although the content of the insulating particles in Reference Example 2 was lower than that in Reference Example 1, Reference Example 2 exhibited a particularly high thermal conductivity in the in-plane direction. One of the reasons why such a result was obtained may be that the percentage of the voids in Reference Example 2 was reduced as compared with Reference Example 1.

The thermally conductive insulation sheet of Reference Comparative Example 1, which was subjected to the vacuum thermal press treatment instead of the roll-press treatment, contained 75 to 97% by area of the insulating particles and 3 to 25% by area of the binder resin, for the entire cross-section perpendicular to the in-plane direction. However, the thermally conductive insulation sheet of Reference Comparative Example 1 had the percentage of voids of more than 10% by area, and exhibited relatively low thermal conductivity in the in-plane direction.

Further, the thermally conductive insulation sheet of Reference Comparative Example 2, which contains less than 75% by area of the insulating particles and more than 25% by area of the binder resin, also exhibited relatively low thermal conductivity in the in-plane direction.

### <<SEM Observation>>

The thermally conductive insulation sheets of Reference Examples 1 to 4, Reference Comparative Examples 1 to 2, and Reference Example 5 were observed by a scanning electron microscope (SEM).

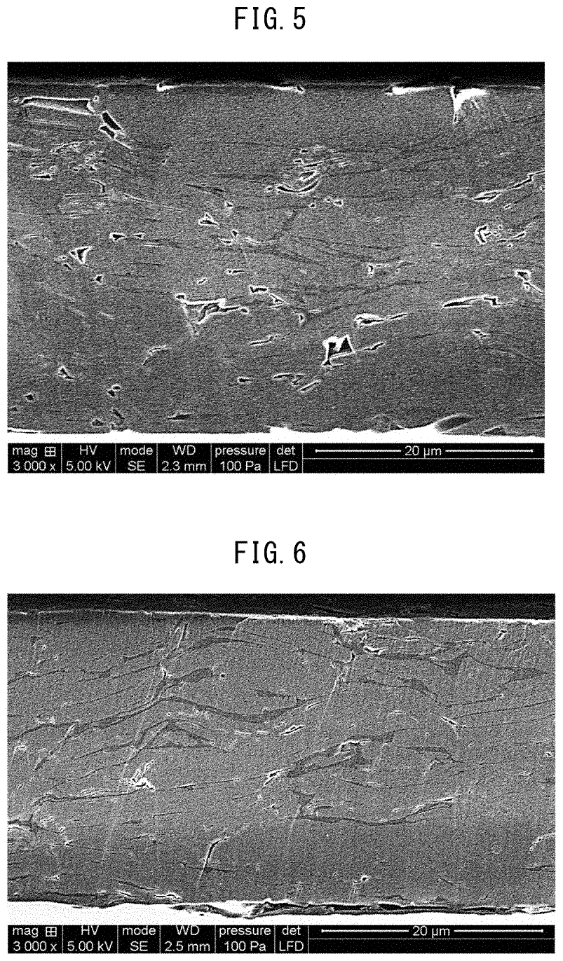

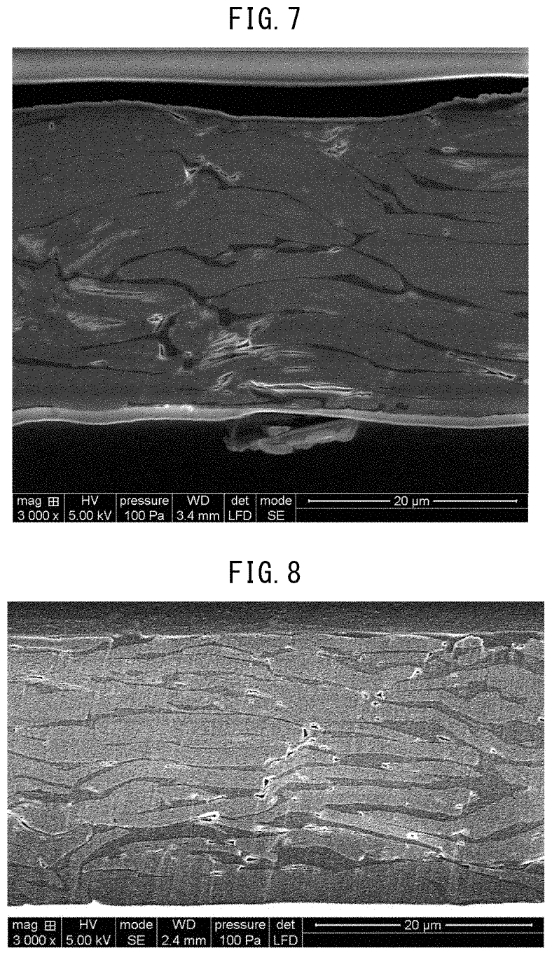

FIG. 5 to FIG. 8 show SEM images of a cross-section perpendicular to the in-plane direction of the thermally conductive insulation sheets according to Reference Examples 1 to 4, respectively. As seen in FIG. 5 to FIG. 8, in the thermally conductive insulation sheets of Reference Examples 1 to 4, flat-shaped boron nitride particles were deformed so as to fill a gap in the sheet, and the voids were relatively small, as compared with, for example, Reference Comparative Example 1 which was subjected to a vacuum hot press treatment (FIG. 10).

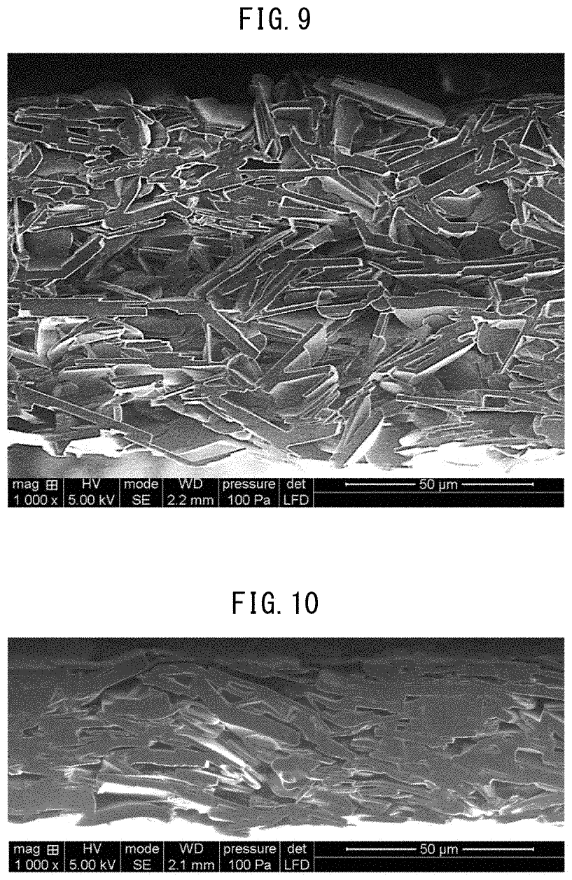

FIG. 9 shows an SEM image of a cross-section perpendicular to the in-plane direction of the thermally conductive insulation sheet precursor according to Reference Example 5. As can be seen from FIG. 9, the sheet of Reference Example 5, which is a thermally conductive insulation sheet precursor not subjected to a press treatment, has relatively large voids and relatively low packing ratio of the insulating particles. Further, deformation of flat-shaped insulating particles was not observed.

FIG. 10 shows an SEM image of a cross-section perpendicular to the in-plane direction of the sheet according to Reference Comparative Example 1. As seen in FIG. 10, in the sheet of Reference Comparative Example 1 which was subjected to a vacuum hot press instead of a roll press treatment during the press treatment, although the voids were reduced as compared with Reference Example 5 which was not subjected to a press treatment, relatively large amount of voids were remained in the thermally conductive insulation sheet due to the three-dimensional hindrance of flat-shaped boron nitrides. Further, as can be seen in FIG. 10, in the thermally conductive insulation sheet of Reference Comparative Example 1, although the flat-shaped insulating particles are deformed to some extent, the degree of deformation is not sufficient to fill the gap between the particles.

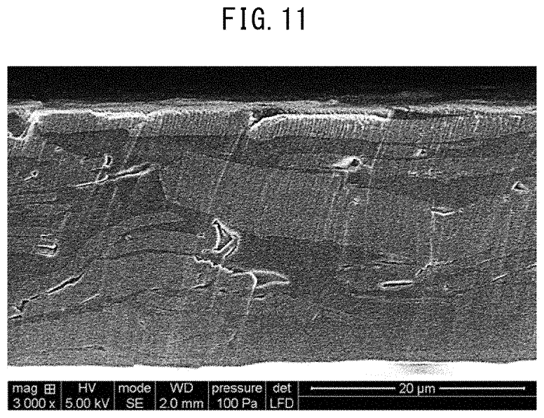

FIG. 11 shows an SEM image of a cross-section perpendicular to the in-plane direction of the sheet according to Reference Comparative Example 2. As can be seen in FIG. 11, in the sheet of Reference Comparative Example 2 which has less than 75% by area of the insulating particles and more than 25% by area of the binder resin, the distances between the insulating particles were relatively large due to the relatively large content of the binder resin.

### Reference Example 6 and Reference Comparative Example 3

Next, surface-insulated metal silicon particles were used in addition to boron nitride particles as insulating particles, and an aramid resin “Conex” (polymetaphenylene isophthalamide: manufactured by Teijin Limited) was used as a binder resin. Thermally conductive insulation sheets according to Reference Example 6 and Reference Comparative Example 3 were prepared and physical properties thereof, etc., were evaluated.

### Reference Example 6 (Ref.Ex.6)

A thermally conductive insulation sheet having the thickness of 56 μm (the thermally conductive insulation sheet of Reference Example 6) was prepared in the same manner as in Reference Example 3, except that 20 parts by volume of the aramid resin “Conex” as a binder resin was dissolved in 130 parts by volume of 1-methyl-2-pyrrolidone, and then, as insulating particles, 60 parts by volume of scaly boron nitride particles “PT110” and 20 parts by volume of metal silicon particles “#350” (manufactured by KINSEI MATEC Co. LTD.; mean particle diameter of 15 μm; aspect ratio of 1), the surface of the metal silicon particles being insulated by a thermal oxidizing method (at 900° C. for 1 hour in air), were added, and a bar coater having a clearance of 0.40 mm was used.

### Reference Comparative Example 3 (Ref.Comp.3)

In order to obtain a thermally conductive insulation sheet with the thickness of 50 μm (thermally conductive insulation sheet of Reference Comparative Example 3), a thermally conductive insulation sheet was prepared in the same manner as in Reference Example 3, except that 40 parts by volume of aramid resin “Technora” as a binder resin was dissolved in 520 parts by volume of 1-methyl-2-pyrrolidone, and then 60 parts by volume of boron nitride particles “PT110” as insulating particles were added, and a bar coater with a clearance of 0.80 mm was used.

The results of the measurements performed for Reference Example 6 and Reference Comparative Example 3 are shown in Table 2.

### [Table 2]

TABLE 2

| | | | | | | Ref. |
|---|---|---|---|---|---|---|
| | | | | | Ref. | Comp. |
| | | | | Unit | Ex.6 | 3 |
| Compo- | insulating | flat- | boron | Parts by | 60 | 60 |
| sition | particles | shaped | nitride | volume | | |
| | | | (PT110) | | | |
| | | spherical | Surface- | Parts by | 20 | — |
| | | | insulated | volume | | |
| | | | metal | | | |
| | | | silicon | | | |
| | | | particles | | | |

| | | | | |
|---|---|---|---|---|
| binder | aramid resin | Parts by | — | 40 |
| resin | “Technora” | volume | | |
| | aramid resin | Parts by | 20 | — |
| | “Conex” | volume | | |

| | Solvent | Parts by | 130 | 520 |
|---|---|---|---|---|
| | | volume | | |
| Manufacturing method (press) | | — | roll | roll |
| | | | press | press |
| Charac- | thermal conductivity | W/m · | 24 | 8 |
| teristics | (in-plane direction) | K | | |
| | thermal conductivity | W/m · | 3.0 | 0.4 |
| | (thickness direction) | K | | |
| | dielectric breakdown voltage | kV/mm | 6.1 | — |
| | bulk density | g/cm³ | 1.84 | 1.79 |
| | insulating particles | % by | (77.3) | (58.9) |
| | | area | | |
| | binder resin | % by | (19.3) | (39.3) |
| | | area | | |
| | voids | % by | 3.4 | 1.8 |
| | | area | | |

As can be seen from Table 2, in the thermally conductive insulation sheet of Reference Examples 6 containing 75 to 97% by area of insulating particles, 3 to 25% by area of the binder resin, and 10% by area or less of voids for the entire cross-section perpendicular to the in-plane direction, a relatively high thermal conductivity in the in-plane direction was observed, as compared with the thermally conductive insulation sheet of Reference Comparative Example 3 in which the insulating particles were less than 75% by area and the binder resin was more than 25% by area. Since the thermally conductive insulation sheet of Reference Example 6 contains metal silicon particles in addition to the boron nitride particles, it exhibits higher thermal conductivity in the thickness direction than Reference Example 4.

### INDUSTRIAL APPLICABILITY

The heat dissipation sheet of the present invention can be suitably used as an insulating heat dissipation member for a heat generating member in an electronic or electrical equipment, for example, as an insulating heat dissipation member for dissipating heat of a semiconductor to a coolant or housing.

### REFERENCE SIGNS LIST

10 heat dissipation sheet
21, 31, 41 insulating particle
22, 32, 42 binder resin
23, 33, 43 void
A, A′, X thermally conductive insulation layer
B adhesive insulation layer
D thickness direction of the heat-dissipation sheet
S in-plane direction of the heat-dissipation sheet

1. A heat dissipation sheet having a structure in which at least two thermally conductive insulation layers are laminated,
wherein the lamination direction of the thermally conductive insulation layers is substantially perpendicular to the thickness direction of the heat dissipation sheet, and
wherein for the entire cross-section perpendicular to the in-plane direction of the heat dissipation sheet, the thermally conductive insulation layer contains 75 to 97% by area of insulating particles, 3 to 25% by area of a binder resin, and 10% by area or less of voids.

2. The heat dissipation sheet according to claim 1, further comprising an adhesive insulation layer arranged between the at least two thermally conductive insulation layers.

3. The heat dissipation sheet according to claim 1, wherein the thermally conductive insulation layers represent at least 50% by volume of the heat dissipation sheet.

4. The heat dissipation sheet according to claim 2, wherein the thickness of the thermally conductive insulation layer in the lamination direction is at least twice the thickness of the adhesive insulation layer in the lamination direction.

5. The heat dissipation sheet according to claim 1, wherein the insulating particles comprise flat-shaped particles that are deformed.

6. The heat dissipation sheet according to claim 1, wherein the insulating particles include 50% by volume or more of boron nitride particles.

7. The heat dissipation sheet according to claim 1, wherein a melting point or a thermal decomposition temperature of the binder resin is 150° C. or higher.

8. The heat dissipation sheet according to claim 1, wherein the binder resin is an aramid resin.

9. The heat dissipation sheet according to claim 1, having the thermal conductivity in the thickness direction of 20 W/(m·K) or more, and the dielectric breakdown voltage of 5 kV/mm or more.

10. The heat dissipation sheet according to claim 1, having 6 or less of relative permittivity at 1 GHz.

11. A method for manufacturing the heat dissipation sheet according to claim 1, comprising:
providing thermally conductive insulation sheets,
laminating the at least two thermally conductive insulation sheets to obtain a laminate, and
slicing the laminate substantially along the lamination direction of the thermally conductive insulation sheets to obtain a heat dissipation sheet,
wherein for the entire cross-section of the thermally conductive insulation sheet perpendicular to the in-plane direction, the thermally conductive insulation sheet contains 75 to 97% by area of insulating particles, 3 to 25% by area of a binder resin, and 10% by area or less of voids.

12. The method according to claim 11, in which, when laminating the at least two thermally conductive insulation sheets, an adhesive insulation material is further arranged between the thermally conductive insulation sheets.

13. The method according to claim 11, in which the thermally conductive insulation sheet has the thermal conductivity of 30 W/(m·K) or more in the in-plane direction.

14. The method according to claim 11, wherein the insulating particles comprise flat-shaped particles.

15. The method according to claim 11, wherein the insulating particles include 50% by volume or more of boron nitride particles.
